(19) United States
(12) Patent Application Publication
(10) Pub. No.: US 2026/0185510 A1
(43) Pub. Date: Jul. 2, 2026

(54) ACTUATING ASSEMBLY AND ACTUATOR

(71) Applicant: Luxshare Intelligent Manufacture Technology (Changshu) Co., Ltd., Changshu City, (CN)

(72) Inventors: Zih-Shuo Huang, Changshu City (CN); Po-Ying Tseng, Changshu City (CN)

(73) Assignee: Luxshare Intelligent Manufacture Technology (Changshu) Co., Ltd., Changshu City (CN)

(21) Appl. No.: 19/418,566

(22) Filed: Dec. 12, 2025

(30) Foreign Application Priority Data
Dec. 31, 2024 (CN) 202412000446.0

(51) Int. Cl. F03G 7/06; H05K 1/181; H05K 3/321

(52) U.S. Cl. CPC F03G 7/06143; H05K 1/181; H05K 3/321

(57) ABSTRACT

Provided are an actuating assembly and an actuator. The actuating assembly includes a circuit board, a fixing member, and an actuating line. The fixing member includes a first conductive layer, a conductive adhesive layer, and a cover plate. Two ends of the actuating line extend into the conductive adhesive layer and electrically connected to the conductive adhesive layer. The conductive adhesive layer is electrically connected to the first conductive layer. The first conductive layer is electrically connected to the circuit board. The first conductive layer and the conductive adhesive layer are welded by heating.

### CROSS-REFERENCE TO RELATED APPLICATION

This application claims the benefit of Chinese Patent Application No. 202412000446.0, filed on Dec. 31, 2024, entitled “Actuating assembly and Actuator”, which is incorporated herein by reference in its entirety.

### FIELD OF DISCLOSURE

The present disclosure relates to an actuating assembly and an actuator.

### BACKGROUND

At present, a micro displacement is controlled by an actuator, the movement of the actuator is controlled by an actuating line. The actuating line is typically made of a shape memory alloy line. If the environment temperature changes, the shape of the shape memory alloy line changes. In application a current is applied to the actuating line made of shape memory alloy to generate heat, the environment temperature around the actuating line changes, and the shape of the actuating line changes. Therefore, the actuator causes a micro displacement of an external device. The environment temperature around the actuating line is changed by changing the current, so a user can control the deformation of the actuating line, thereby achieving the effect of the actuator.

In existing actuators, the actuating line is fixed by a line clip, but the actuating line has a small diameter. Fixing failure or breaking of the actuating line caused by clipping may occur when the actuating line is fixed by the line clip. In addition, the line clip has a certain volume, the volume of the actuator is difficulty to scaling down.

### SUMMARY

The present disclosure provides an actuating assembly and an actuator.

One aspect of embodiments of the present disclosure provides an actuating assembly, The actuating assembly includes: a circuit board, a fixing member, and an actuating line. The circuit board is provided with an integrated circuit component extending to an edge of the circuit board. The fixing member is arranged at an edge of the circuit board and includes a first conductive layer, a conductive adhesive layer, and a cover plate. The first conductive layer, the conductive adhesive layer, and the cover plate are sequentially stacked. The first conductive layer is electrically connected to the integrated circuit component and the conductive adhesive layer. Two ends of the actuating line extend into the conductive adhesive layer and are electrically connected to the conductive adhesive layer, and the actuating line and the circuit board form a closed structure.

Another aspect of embodiments of the present disclosure provides an actuator, The actuator includes: an actuator body, a brake member, a swing arm, a first driving member, and a second driving member. A top surface of the actuator body is provided with a first rotating shaft and a second rotating shaft. The brake member is disposed on the top surface of the actuator body and rotationally connected to the first rotating shaft. An end of an edge of the brake member close to the actuator body protrudes to form a first rotating member. The swing arm is disposed on the top surface of the actuator body and rotationally connected to the second rotating shaft, a second rotating member protrudes from the swing arm, and an end of the swing arm close to the brake member abuts against the brake member.

Each of the first driving member and the second driving member includes a circuit board a fixing member, and an actuating line. The circuit board is provided with an integrated circuit component extending to an edge of the circuit board. The fixing member is arranged at an edge of the circuit board and includes a first conductive layer, a conductive adhesive layer, and a cover plate. The first conductive layer, the conductive adhesive layer, and the cover plate are sequentially stacked. The first conductive layer is electrically connected to the integrated circuit component and the conductive adhesive layer. Two ends of the actuating line extend into the conductive adhesive layer and are electrically connected to the conductive adhesive layer, and the actuating line and the circuit board form a closed ring structure. The first driving member and the second driving member are both disposed on the top surface of the actuator body, the first actuating line of the first driving member is connected to the first rotating member, and the second actuating line of the second driving member is connected to the second rotating member.

### BRIEF DESCRIPTION OF DRAWINGS

The various features and advantages of the disclosed examples will become apparent to those skilled in the art from the detailed description. The figures that accompany the detailed description can be briefly described as follows:

FIG. 1 is a schematic front perspective view of an actuating assembly according to an embodiment of the present disclosure;

FIG. 2 is a front view of the actuating assembly according to an embodiment of the present disclosure;

FIG. 3 is a sectional view of the actuating assembly according to an embodiment of the present disclosure;

FIG. 4 is a schematic rear perspective view of the actuating assembly according to an embodiment of the present disclosure;

FIG. 5 is a schematic front perspective view of another actuating assembly according to an embodiment of the present disclosure;

FIG. 6 is a schematic rear perspective view of the actuating assembly according to an embodiment of the present disclosure;

FIG. 7 is a schematic front perspective view of an actuating assembly with a cover plate, a second conductive layer and a conductive adhesive layer being omitted according to an embodiment of the present disclosure;

FIG. 8 is a schematic perspective view of a fixing member and an actuating line including a curved segment according to an embodiment of the present disclosure;

FIG. 9 is a schematic perspective view of a fixing member and an actuating line including a curved segment with a second conductive layer and a conductive adhesive layer being omitted according to an embodiment of the present disclosure;

FIG. 10 is a schematic front perspective view of an actuator according to an embodiment of the present disclosure;

FIG. 11 is a schematic rear perspective view of an actuator according to an embodiment of the present disclosure;

FIG. 12 is a front view of an actuator according to an embodiment of the present disclosure;

FIG. 13 is a sectional view of a part of an actuator according to an embodiment of the present disclosure;

FIG. 14 is a sectional view of a fixing member before manufacturing according to an embodiment of the present disclosure;

FIG. 15 is a top view showing arrangement of first conductive components on a circuit board according to an embodiment of the present disclosure;

FIG. 16 is a sectional view of the formed fixing member according to an embodiment of the present disclosure;

FIG. 17 is sectional view of another fixing member before manufacturing according to an embodiment of the present disclosure;

FIG. 18 is a top view showing arrangement of second conductive components on a circuit board according to an embodiment of the present disclosure;

FIG. 19 is a sectional view of the formed fixing member according to an embodiment of the present disclosure;

FIG. 20 is a sectional view of another fixing member before manufacturing according to an embodiment of the present disclosure;

FIG. 21 is a sectional view of the formed fixing member according to an embodiment of the present disclosure;

FIG. 22 is a schematic view of an electronic device according to an embodiment of the present disclosure;

FIG. 23 is a schematic view of another electronic device according to an embodiment of the present disclosure; and

FIG. 24 is a schematic view of an electronic device according to an embodiment of the present disclosure.

### DETAILED DESCRIPTION

The present disclosure is described below based on embodiments, but is not limited to these embodiments. Details are described in the following detailed description of the present disclosure. Those skilled in the art can fully understand the present application without these details. To avoid confusing the essence of the present disclosure, well known method, process, flow, element and circuit are not described in detail in the present disclosure.

In addition, those of ordinary skill in the art should understand that the accompanying drawings provided herein are for illustrative purposes only, and the accompanying drawings are not necessarily drawn to scale.

Unless otherwise stated or defined, the terms “install”, “couple”, “connect”, “fix” and the like should be understood in a broad sense. For example, the term “connect” may be fixedly connected or detachably connected or integrally connected, may be mechanically connected or electrically connected, may be directly connected or indirectly connected by means of an intermediate medium, and may be internally communicated or have an interaction relationship between two elements. A person skilled in the art can understand the specific meanings of the above terms in the present disclosure according to specific circumstances.

Further, spatially relative terms, such as “inside”, “outside”, “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Unless otherwise stated, the terms “comprise”, “include” and the like in the entire application document shall be interpreted as inclusive rather than exclusive or exhaustive; in other words, the terms mean “include but not limited to”.

In the descriptions of the present disclosure, terms like “first”, “second” and the like are used for the purpose of description only, but cannot be considered to indicate or imply relative importance. In addition, in the descriptions of the present disclosure, unless otherwise stated, the meaning of “a plurality of” is two or more.

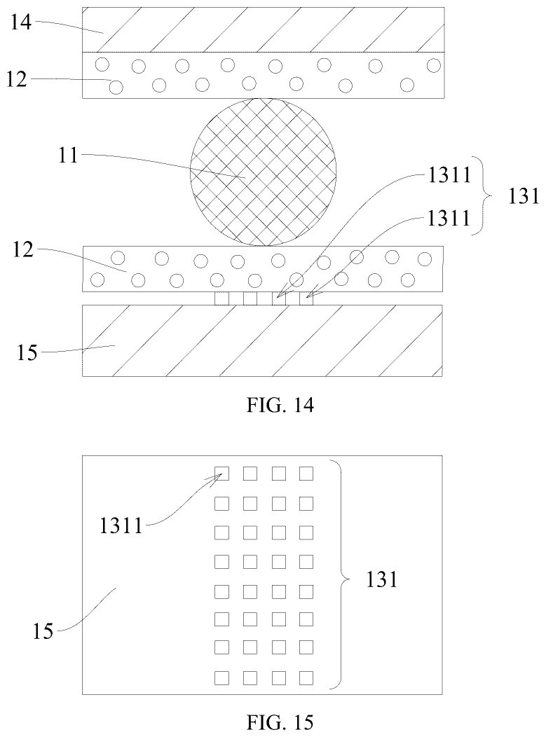

Anisotropic Conductive Film (ACF) is a type of electronic material and is composed of conductive particles and insulating adhesive material. The anisotropic conductive film exhibits different conductive properties at different positions. Positions where conductive particles are dispersed cannot form effective current paths and thus show insulation, while positions where conductive particles are concentrated or a conductive particle cluster is disintegrated can form effective current paths and thus show conductivity. Therefore, the anisotropic conductive film has adhesion properties and conducts electricity only in a direction perpendicular to a compressed plane. To enable both current conduction and adhesive fixation between circuit components, anisotropic conductive film is used as a conductive adhesive layer 12, as shown in FIG. 14 to FIG. 16. When forming a fixing component, heating and pressurizing treatments is applied to the anisotropic conductive film, so that the conductive particle cluster is disintegrated, the anisotropic conductive film is weld with a circuit component, thereby achieving both conduction and fixation. For a fixing member formed by heating and pressurizing treatments, the conductive particles are concentrated between an actuating line 11 and a first conductive layer 131 and form a conductive path between the actuating line 11 and the first conductive layer 131. Insulating adhesive material fills remaining positions. As a result, the conductive adhesive layer 12 conducts electricity only in the vertical direction, thereby achieving one-dimensional conduction. In addition, the insulating adhesive material provides stable and reliable connections between a cover plate 14, the actuating line 11 and the first conductive layer 131, the first conductive layer 131 is welded to a circuit board 15, and thus, an effective fixing structure is formed.

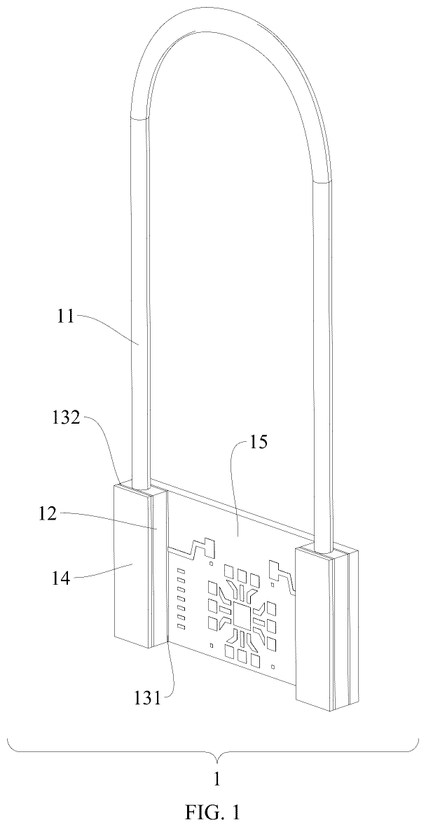

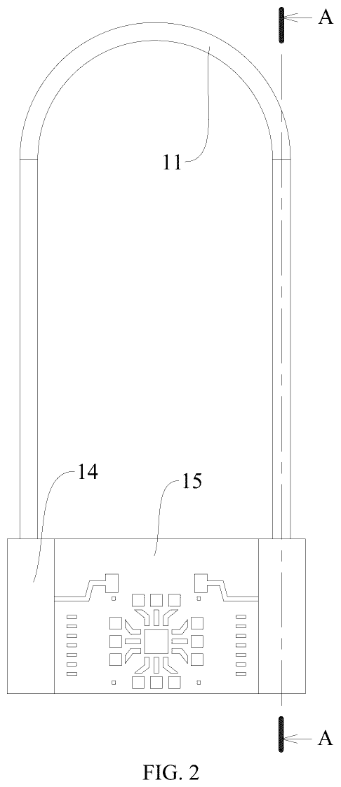

Embodiments of the present disclosure provide an actuating assembly 1. As shown in FIG. 1 and FIG. 2, the actuating assembly 1 includes a circuit board 15, at least one fixing member, and an actuating line 11. The actuating line 11 is fixed to the circuit board 15 by the fixing member, thereby achieving a stable and effective connection, avoiding fixing failure and breaking of the actuating line 11, and enabling miniaturization without occupying excessive space. The number of the fixing member is not limited and may be increased or reduced according to actual conditions to ensure that the actuating line 11 is effectively fixed. Material of the actuating line 11 may be shape memory alloy. The circuit board 15 supplies, through the fixing member, a current into the actuating line 11, generating Joule heat on the actuating line 11. The Joule heat causes deformation of the actuating line 11, achieving the driving of an external component. An integrated circuit component is provided on the circuit board 15. The integrated circuit component extends to an edge of the circuit board 15 and is electrically connected to the fixing member, thereby achieving a circuit conduction. The actuating line 11 is located on the outer side of the circuit board 15. Two ends of the actuating line 11 extend into the fixing member for electrical connection. As a result, the actuating line 11, the fixing member, and the circuit board 15 together form a closed ring structure. For example, the part of the actuating line 11 located outside of the circuit board 14 forms a U-shaped like structure, and the actuating assembly 1 controls movement of an external component through this U-shaped part. Heating the actuating line 11 causes shape change of the actuating line 11, and the shape change of the actuating line 1 causes changes such as length of the actuating line 11, which can drive the external component to move in a controllable small range. For example, by changing the current according to the required movement amplitude, the deformation amplitude of the actuating line 11is controlled.

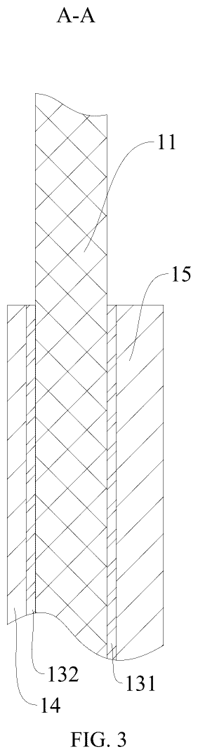

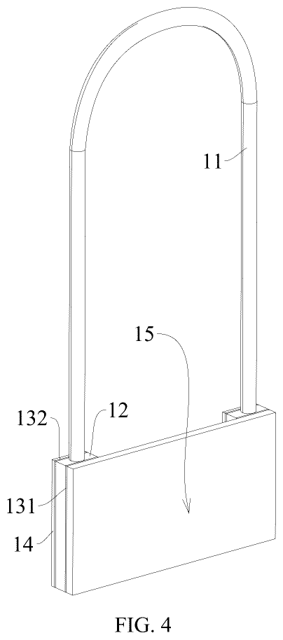

The actuating assembly 1 includes at least one fixing member. The number of the fixing member is not limited. FIG. 3 is a cross-sectional view taken along a line A-A in FIG. 2. As shown in FIG. 1 to FIG. 4, each fixing member includes a first conductive layer 131, a conductive adhesive layer 12, and a cover plate 4. The conductive adhesive layer 12 is disposed between the first conductive layer 131 and the cover plate 14, and the actuating line 11 extends into the conductive adhesive layer 12 and is fixed by the conductive adhesive layer 12. The first conductive layer 131 is disposed on the circuit board 15 and electrically connected to the circuit board 15. The achieve efficient conduction between the integrated circuit component on the circuit board 15 and the conductive adhesive layer 12 is achieved by the first conductive layer 131. To achieve a more stable and effective fixation, the conductive adhesive layer 12 is disposed on the first conductive layer 131 and is electrically connected to the first conductive layer 131. Therefore, the electrical connection and fixation between the first conductive layer 131 and the actuating line 11 is achieved by the conductive adhesive layer 12. The conductive adhesive layer 12 is not fully conductive; instead, its conductivity is achieved through disintegration of conductive particle clusters inside the conductive adhesive layer 12 during processing. The integrated circuit component is relatively precision-made. Therefore, the first conductive layer 131 avoids the problems of low conduction efficiency and poor heat dissipation that occur when the integrated circuit component is directly connected to the conductive adhesive layer 12. The cover plate 14 is made of an insulating material, which prevents electric leakage and protects the fixing member.

According to the actual situation, the maximum tensile strength of the current shape memory alloy wire is generally 50 Newtons. When the actuating assembly 1 is in operation, for the actuating line 11 that generates a tensile force of 1 Newton, a length of about 400 microns of this actuating line 11 needs to be fixed to achieve effective and stable fixation. Therefore, at least a length of about 20 millimeters of the actuating line 11 needs to be fixed. Moreover, to enable the manufactured actuating assembly 1 to drive the external component to move stably and effectively, it is necessary to fix a section of the actuating line 11 with a length of about 30 microns at minimum in terms of feasibility. Therefore, the length of the section of the actuating line 11 fixed in the conductive adhesive layer 12 ranges from 0.03 millimeters to 20 millimeters.

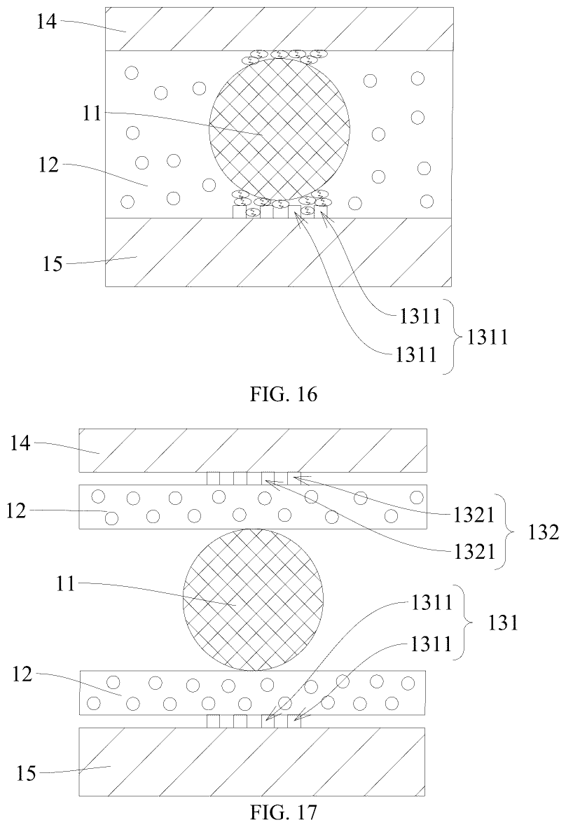

In some embodiments, the first conductive layer 131 is a metal contact layer. As shown in FIG. 14, FIG. 15 and FIG. 16, the first conductive layer 131 includes at least two first conductive components 1311. The first conductive component 1311 is a metal contact. For example, the first conductive layer 131 includes at least two first conductive components 1311 arranged in an array. The shape and size of the first conductive layer 131 are determined by the shape and size of the projection of the actuating line 11 on the circuit board 15, and the number of the first conductive components 1311 depends on the shape and size of the first conductive layer 131. Each first conductive component 1311 is electrically connected to the conductive layer 12 and the circuit board 15. At a side close to the circuit board 15, the first conductive components 1311 (the metal contacts) achieve more efficient and precise electrical connection with the integrated circuit component, thereby enabling effective conduction. At a side close to the conductive adhesive layer 12, an array of first conductive components 1311 of the first conductive layer 131 has a relatively large surface area, which achieves better bonding with the conductive particles in the conductive adhesive layer 12, thereby enhancing the bonding force between the first conductive layer 131 and the conductive adhesive layer 12, realizing a tighter connection after welding, and avoiding fixation failure. The cover plate 14 is disposed on the conductive adhesive layer 12 to protect the fixing structure.

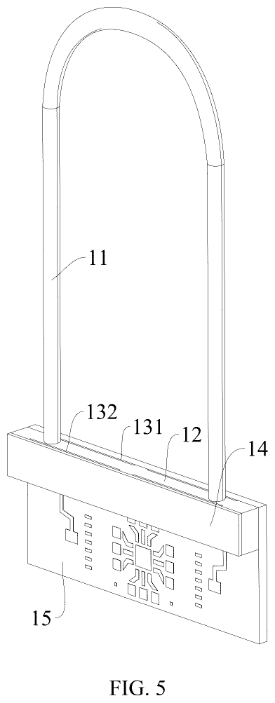

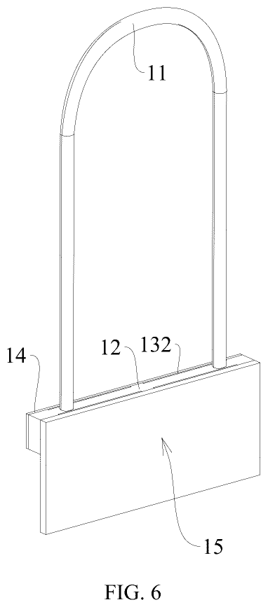

In some embodiments, as shown in FIG. 5 and FIG. 6, the number of the fixing member is one, and the one fixing member is disposed on an end of the circuit board 15 in a width direction. To maximize the length of the fixing member used for fixing the actuating line 11, two sections of the actuating line 11 extend into the conductive adhesive layer 12 of the fixing member via two ends of the conductive adhesive layer 12 in a length direction, and further extend into a middle portion of the conductive adhesive layer 12, and two ends of the actuating line 11 are covered by the middle portion of the conductive adhesive layer 12. This maximizes the utilization of space within the fixing member, achieves a better fixing effect, and prevents the actuating line 11 from fixing failure or breaking. The first conductive layer 131 covers a projection of the actuating line 11 on the circuit board 15. Therefore, the contact area between the first conductive layer 131 and the actuating line 11, as well as the contact area between the first conductive layer 131 and the conductive adhesive layer 12 disposed between the first conductive layer 131 and the actuating line 11 are increased, and efficient conduction and tight bonding are achieved between the actuating line 11 and the first conductive layer 131. Compared with a wire clamp, the space occupied by the fixing member is significantly reduced.

As shown in FIG. 5 to FIG. 7, the first conductive layer 131 includes two first conductive sheets arranged on the circuit board 15 and spaced apart from each other. The two first conductive sheets serve as a positive electrode and a negative electrode of a circuit for the actuating line 11 respectively. Each first conductive sheet is composed of metal contacts for increasing a contact area to achieve a more stable connection and more efficient conduction. For example, each first conductive sheet includes first conductive components 1311 arranged in an array. The conductive adhesive layer 12 is disposed on the two first conductive sheets to achieve electrical conduction between the first conductive sheets and the actuating line 11. The conductive adhesive layer 12 further fills a gap between the two first conductive sheets and is connected to the circuit board 15. In addition, two ends of the conductive adhesive layer 12 extend beyond the two first conductive sheets and extend to two edges of the circuit board 15 in the length direction respectively. The conductive adhesive layer 12 conducts electricity only in the vertical direction (the direction perpendicular to the plane of the circuit board 15). Therefore, the conductive adhesive layer 12 located between the two first conductive sheets is insulating in a direction parallel to the plane of the circuit board 15, and will not cause electrical conduction between the two first conductive sheets (which serve as the positive electrode and the negative electrode) and thus will not cause a short circuit. Meanwhile, the conductive adhesive layer 12 also has the function of adhesive fixation. The parts of the conductive adhesive layer 12 that are disposed between the two first conductive sheets and extend to the edges of the circuit board 15 make the structure of the entire fixing member more stable and reliable, avoid fixation failure and breakage of the actuating line 11, and significantly reduce the space occupied by the fixing member compared with wire clamp.

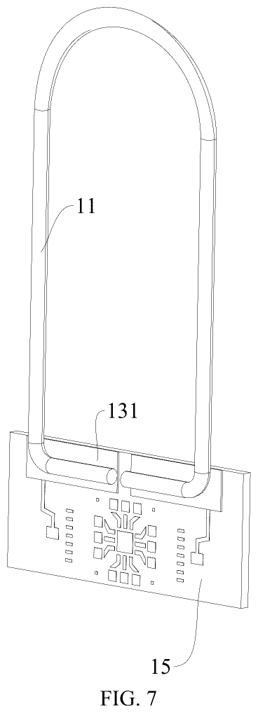

As shown in FIG. 7, the fixing member is disposed an end of the circuit board 15 in the width direction, two ends of the actuating line 11 extending into the fixing member form an opposite positional relationship. According to the actual situation, the two ends of the actuating line 11 extending into the fixing member may either be in contact or not in contact. When the actuating line 11 generates Joule heat when an electric current flows through the actuating line 11, the actuating line 11 undergoes deformation.

In some embodiments, as shown in FIG. 1 to FIG. 4, the number of the fixing members is two. The two fixing members are located at two ends of the circuit board 15 in the length direction respectively. To maximize the length of the fixing member for fixing the actuating line 11, two ends of the fixing member extend to edges of the circuit board 15. Two ends of the actuating line 11 extend into the conductive adhesive layer 12 respectively from two ends of the two fixing members, and reach the bottom of the conductive adhesive layer 12 in the length direction. The two ends of the two fixing members are located on a same side of the two fixing members in the length direction of the fixing members. In this way, maximum utilization of the length of the fixing member is achieved. The two first conductive layers 131 serve as the positive electrode and the negative electrode respectively. The two first conductive layers 131 cover the projection of the actuating line 11 on the circuit board 15. This design increases the contact area between the first conductive layers 131 and the actuating line 11, as well as the contact area between the first conductive layers 131 and the conductive adhesive layer 12 which is disposed between the first conductive layers 131 and the actuating line 11. In turn, it enables efficient conduction and tight bonding between the actuating line 11 and the first conductive layers 131, while avoiding fixation failure and breakage of the actuating line 11.

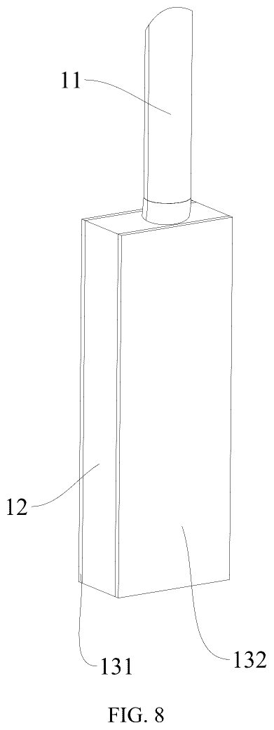

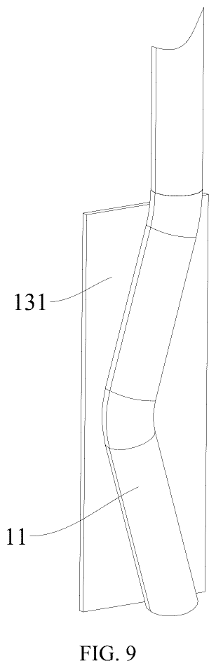

In some embodiments, as shown in FIG. 7, FIG. 8, and FIG. 9, the part of the actuating line 11 extending into the conductive adhesive layer 12 may be parallel to the edge of the conductive adhesive layer 12, or may have at least one curved segment. This is to increase the projection area of the actuating line 11 on the circuit board 15, achieve a tighter and more reliable connection and more efficient conduction, and significantly reduce the occupied space compared with the wire clamp.

In some embodiments, as shown in FIG. 1 to FIG. 8, and FIG. 17 to FIG. 21, the actuating assembly 1 further includes a second conductive layer 132, and the second conductive layer 132 is disposed between the conductive adhesive layer 12 and the cover plate 4. The second conductive layer 132 achieves a tighter connection between the cover plate 14 and the conductive adhesive layer 12. The cover plate 14 is made of an insulating material. Therefore, the connection between the cover plate 14 and the conductive adhesive layer 12 is mainly achieved through the adhesion of the insulating adhesive material. The second conductive layer 132 is made of a metal material. The second conductive layer 132 forms a further welding connection with the conductive particles generated from conductive particle clusters during heating and pressing. This makes the bonding between the cover plate 14 and the conductive adhesive layer 12 tighter and more reliable, and prevents fixation failure. In addition, the second conductive layer 132 causes the current to flow in a more complex manner inside the actuating line 11, enhancing circuit conduction and the generation of Joule heat. Since the second conductive layer 132 plays the role of auxiliary connection and enhancing circuit conduction, its area may be reduced to minimize metal usage. The second conductive layer 132 includes one or more second conductive components 1321. The second conductive component 1321 is electrically connected to the conductive adhesive layer 12. The second conductive member 1321 is a micro metal structure such as a metal microsphere, which achieves the effect of cooperative welding with the conductive particles in the conductive adhesive layer 12.

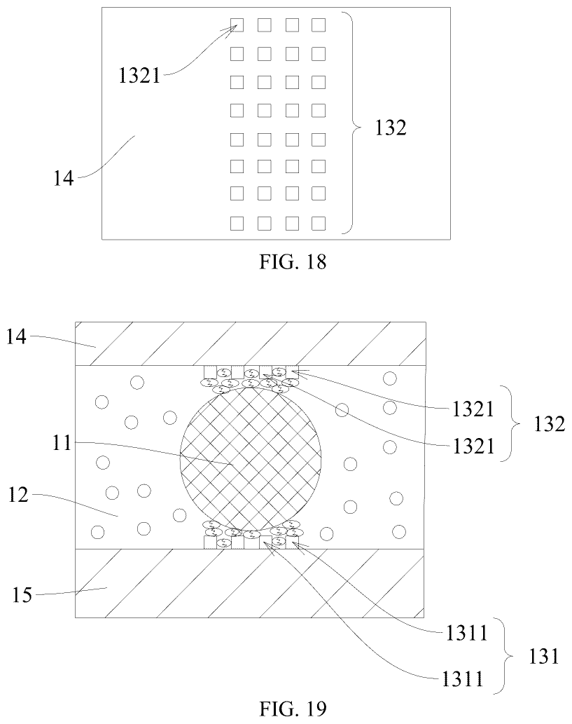

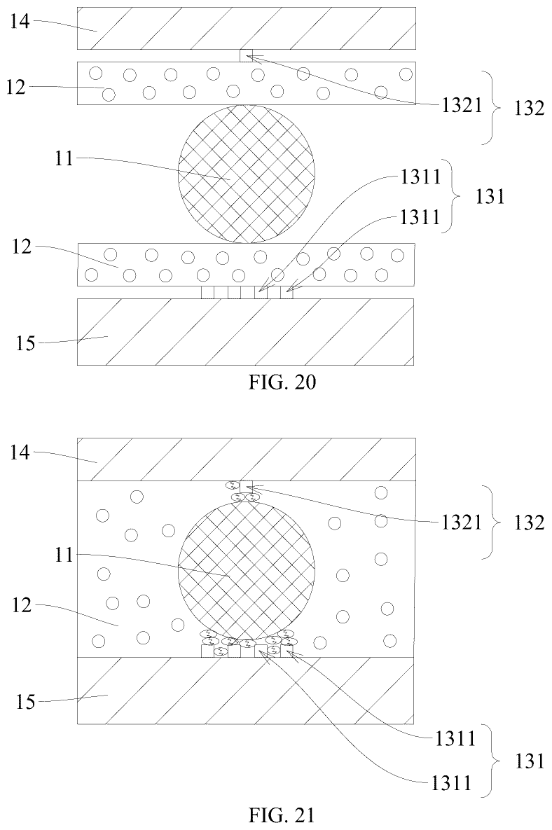

In some embodiments, as shown in FIG. 17, FIG. 18, and FIG. 19, the second conductive layer 132 includes at least two second conductive components 1321, positions of the second conductive components 1321 are in one-to-one correspondence with positions of the first conductive components 1311. For example, the second conductive components 1321 and the first conductive components 1311 are symmetrically arranged on two sides of the actuating line 11. Since the conductive adhesive layer 12 is conductive in the vertical direction, the second conductive component 1321 assists in the current distribution within the actuating line 11, thereby enhancing current conduction and Joule heat generation. In alternative embodiments, as shown in FIG. 20 and FIG. 21, the second conductive layer 132 includes one second conductive component 1321, the position of the second conductive component 1321 corresponds to the actuating line 11, and the second conductive component 1321 is located within the projection of the actuating line 11 on the circuit board 15, and also enhances the current conduction and Joule heat generation through the electrical conduction of the conductive adhesive layer 12 in the vertical direction.

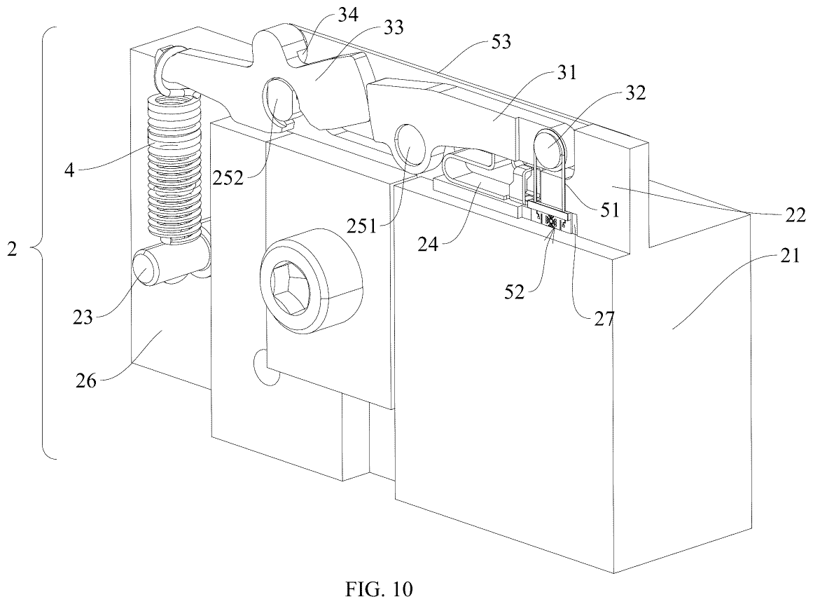

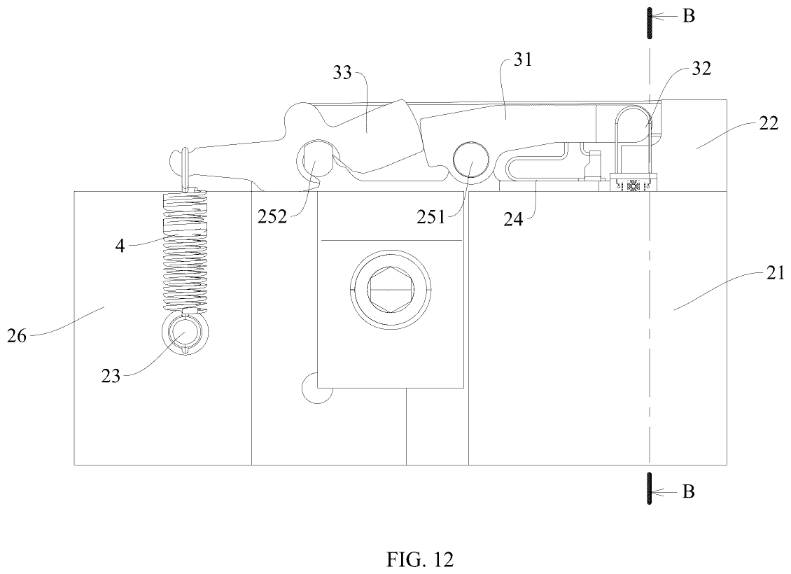

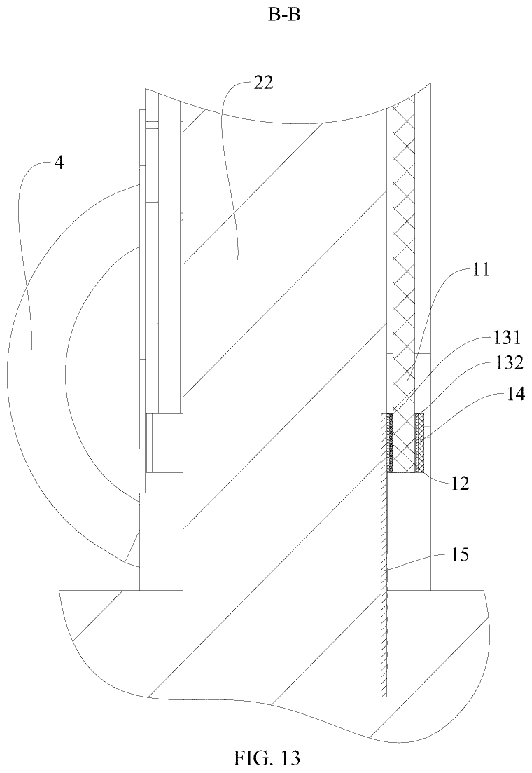

Embodiments of the present disclosure further provide an actuator 2. FIG. 13 is a cross-sectional view taken along line B-B in FIG. 12. As shown in FIG. 10 to FIG. 13, the actuator 2 includes an actuator body 21, a brake member 31, a swing arm 33, a first driving member 52, and a second driving member 54. The brake member 31, the swing arm 33, the first driving member 52, and the second driving member 54 are arranged on the actuator body 21. The brake member 31 abuts against the swing arm 33. The brake member 31 and the swing arm 33 are controlled by the first driving member 52, and the second driving member 54 respectively. The displacement generated by the actuator 2 is outputted outward through the swing arm 33, driving a structure to be moved to achieve small and precise movement. A top surface of the actuator body 21 is provided with a first rotating shaft 251 and a second rotating shaft 252 for connecting to the brake member 31 and the swing arm 33. The brake member 31 is arranged on the top surface of the actuator body 21 and is rotatably connected to the first rotating shaft 251. An end of an edge of the brake member 31 close to the actuator body 21 protrudes to form a first rotating member 32. The first rotating member 32 is connected to the first driving member 52. For example, a first actuating line 51 wraps around the first rotating member 32, and the brake member 31 is connected to the first actuating line 51 through the first rotating member 32. When the brake member 31 rotates around the first rotating shaft 251, the first rotating member 32 rotates along with the brake member 31. The swing arm 33 is disposed on the top surface of the actuator body 21 and rotationally connected to the second rotating shaft 252. A second rotating member 34 protrudes from the swing arm 33, and the second rotating member 34 is connected to the second driving member 54. For example, the second actuating line 53 wraps around the second rotating member 34, and the swing arm 31 is connected to the second actuating line 53 through the second rotating member 34. When the swing arm 33 rotates around the second rotating shaft 252, the second rotating member 34. rotates along with the swing arm 33. An end of the swing arm 33 close to the brake member 31 abuts against the brake member 31. The swing arm 33 is driven by the first driving member 52 and the second driving member 54 to switch between a braking state and a releasing braking state. In some embodiments, the actuator 2 further includes a mounting base 22 connected to the top surface of the actuator body 2. The mounting base 22 is used for mounting of structures such as the first driving member 52 and the second driving member 54.

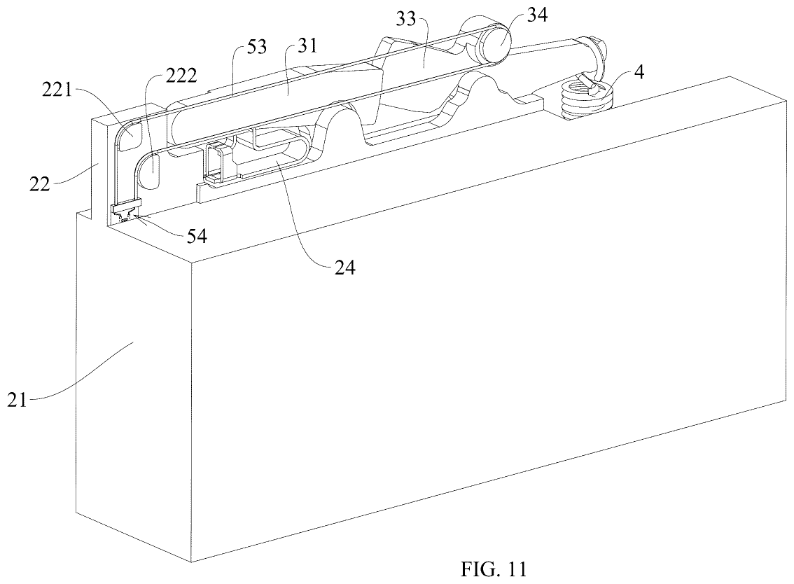

The first driving member 52 and the second driving member 54 adopt the actuating assembly 1. That is, each of the first driving member 52 and the second driving member 54 includes the circuit board 15, the fixing member, and the actuating line 11 described above. As show in FIG. 10 and FIG. 11, the first driving member 52 and the second driving member 54 are respectively disposed on two sides of the mounting base 22 on the top surface of the actuator body 21, and control the brake member 31 and the swing arm 33 respectively. The actuating line of the first driving member 52 is the first actuating line 51, and the actuating line of the second driving member 54 is the second actuating line 53. The first driving member 52 controls the brake member 31 through a first actuator member, and the first actuating line 51 is connected to the first rotating member 32. The first rotating member 32 extends into a ring formed by the first actuating line 51 and the first driving member 52. When a current flows through the first actuating line 51, the first actuating line 51 generates Joule heat. Due to the Joule heat, the first actuating line 51 deforms, and thus the length of the first actuating line 51 changes. When the length of the first actuating line 51 changes, the circumference of the ring formed by the first actuating line 51 and the first driving member 52 changes, the first rotating member 32 is driven by the circumference change, and the brake member 31 rotates around the first rotating shaft 251. For example, as shown in FIG. 10, from the front view of the actuator 2, when the brake member 31 is initially in contact with the swing arm 33 in a braking state, the swing arm 33 is controlled by the brake member 31 and cannot move. The first actuating line 51 drives the brake member 31 to rotate clockwise around the first rotating shaft 251, and the brake member 31 is no longer in contact with the swing arm 33, thereby achieving brake release. At a result, the swing arm 33 is movable. The second driving member 54 controls the swing arm 33 through the second actuator member. The second actuating line 53 is connected to the second rotating member 34. The second rotating member 34 extends into a ring formed by the second actuating line 53 and the second driving member 54. When a current flows through the second actuating line 53, the second actuating line 53 generates Joule heat. Due to the Joule heat, the second actuating line 53 deforms, and thus the length of the second actuating line 53 changes. When the length of the second actuating line 53 changes, the circumference of the ring formed by the second actuating line 53 and the second driving member 54 changes, the second rotating member 34 is driven by the circumference change, and the swing arm 33 rotates around the second rotating shaft 252. For example, as shown in FIG. 10 and FIG. 11, from the front view of the actuator 2 in FIG. 10, after the brake release, the swing arm 33 is movable. The second actuating line 53 drives the swing arm 33 to rotate clockwise around the second rotating shaft 252. At this time, the end of the swing arm 33 away from the mounting base 22, i.e., the movable end, can move in the vertical direction, which is the displacement outputted by the actuator 2.

As shown in FIG. 10, an end of the actuator 2 away from the mounting base 22 extends to form a positioning part 26, and a fixing column 23 is mounted on the positioning part 26. The positioning part 26 may be a positioning table, such as a block shape. A thickness of the positioning part 26 is less than a thickness of the actuator body 21. Therefore, when the swing arm 33 is driven by the second driving member 54 and the second actuating line 53 to move, the positioning part 26 avoids the swing arm 33 to prevent the movement of the swing arm 33 from being affected. The actuator 2 further includes a first elastic member 4 for resetting the moved swing arm 33 and a second elastic member 24 for resetting the moved brake member 31. In some embodiments, the first elastic member 4 and the second elastic member 24 may be elastic structures such as springs, elastic pieces, elastic metal rings, and the like. Structures of the first elastic member 4 and the second elastic member 24 may be selected according to their positions and usage manners. Two ends of the first elastic member 4 are respectively connected to the fixing column 23 and an end of the swing arm 33 away from the brake member 31. When the swing arm 33 moves excessively in the clockwise direction, the elastic force of the compressed first elastic member 4 pulls it back to reset. When the swing arm 33 moves excessively in the counterclockwise direction, the elastic force of the bouncing first elastic member 4 pushes it back to reset. The second elastic member 24 is disposed between the brake member 31 and the actuator body 21 and abuts against both the brake member 31 and the actuator body 21. In some embodiments, the second elastic member 24 is arranged on the side in the rotation direction of the brake member 31 during brake release. For example, when the brake member 31 releases the swing arm 33 by rotating clockwise, the second elastic member 24 is disposed on the right side of the first rotating shaft 251. Therefore, during brake release, the second elastic member 24 is compressed, so that when it is necessary to engage the brake member 31 and the swing arm 33 to the braking state, the second elastic member 24 bounces up to reset the brake member 31.

In some embodiments, as shown in FIG. 11, at least one steering block protrudes from the mounting base 22. The steering block is used for steering the first actuating line 51 or the second actuating line 53 according to requirements and structural design to coordinate with the movement of the brake member 31 and the swing arm 33. For example, as shown in FIG. 11, the least one steering block includes a first steering block 221 and a second steering block 222. The second actuating line 53 is steered by the first steering block 221 and the second steering block 222 and then connected to the second rotating member 34. In this case, there is no need to set the installation position of the second driving member 54 according to the position of the second rotating member 34, instead, the extending direction of the second actuating line 53 is changed by the guiding of the steering blocks. The first actuating line 51 and the second actuating line 53 slide relative to the first rotating member 32, the second rotating member 34 and the steering block when deformed. If the steering block has a sharp shape, the first actuating line 51 and the second actuating line 53 may have a breaking risk. In this embodiment, the edge of the steering block is a smooth arc to prevent the first actuating line 51 and the second actuating line 53 from breaking.

In some embodiments, as shown in FIG. 10, FIG. 11 and FIG. 13, at least one of the first driving member 52 or the second driving member 54 has a part embedded inside the actuator body 21. For example, at least one of the first driving member 52 or the second driving member 54 has a part encapsulated by the actuator body 21. The integrated circuit components on the circuit board 15 are connected to external circuits as needed, thereby realizing the control of the first actuating line 51 and the second actuating line 53. In addition, the part embedded inside the actuator body 21 is protected by the actuator body 21.

In some embodiments, as shown in FIG. 10, the mounting base 22 is further provided with an accommodating groove 27, and at least one of the first driving member 52 or the second driving member 54 is disposed in the accommodating groove 27 to achieve better protection and reduce the impact of dust, collision and the like on the at least one of the first driving member 52 or the second driving member 54.

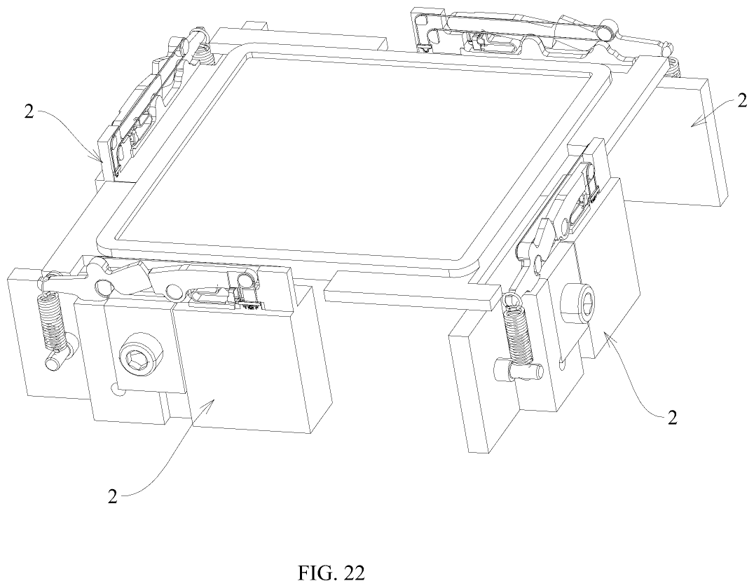

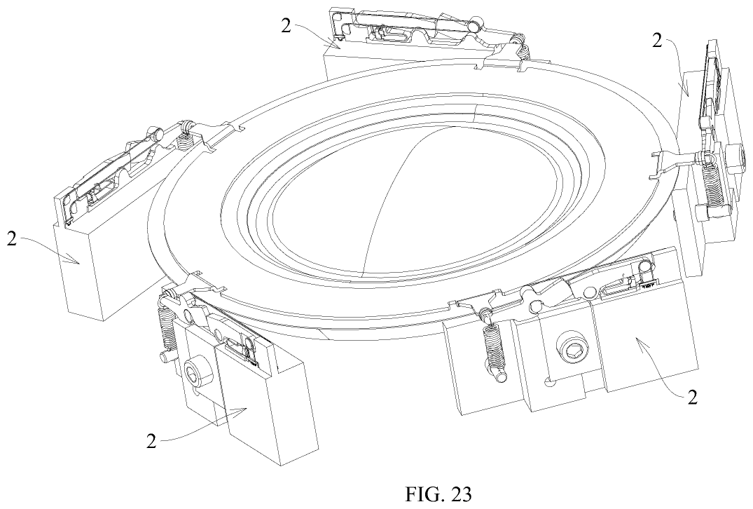

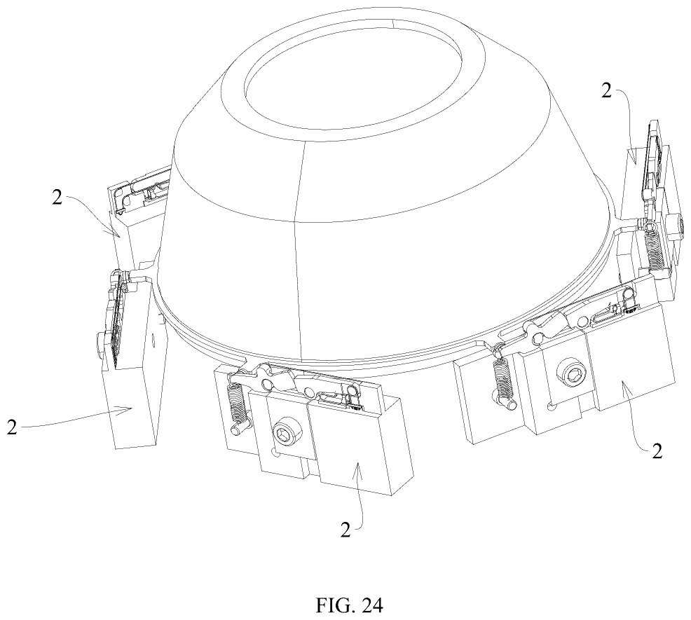

In some embodiments, as shown in FIG. 22, FIG. 23, and FIG. 24, multiple actuators 2 are arranged on structures such as a voice coil, a display screen, a lens module, and the like. Such structure is connected to the swing arm 33 of the corresponding actuator 2 through its connector. The swing arm 33 outputs displacement. Therefore, precise control over micro-movements of such structures is achieved, such as the vibration of the voice coil, the focal length adjustment of lens module. For example, as shown in FIG. 22, each edge of the display screen is connected to the actuator 2. For another example, as shown in FIG. 23, an edge of the voice coil is connected to actuators 2. For yet another example, as shown in FIG. 24, an edge of the lens module is connected to actuators 2. The more actuators 2 are provided, the higher the movement precision of the electronic device. With multiple actuators 2, precise control of the electronic device is improved, product quality is enhanced, and a better user experience is achieved.

Embodiments of the present disclosure provide an actuating assembly and an actuator. The actuating assembly includes a circuit board, a fixing member, and an actuating line. The fixing member includes a first conductive layer, a conductive adhesive layer, and a cover plate. Two ends of the actuating line extend into the conductive adhesive layer and electrically connected to the conductive adhesive layer. The conductive adhesive layer is electrically connected to the first conductive layer. The first conductive layer is electrically connected to the circuit board. The first conductive layer and the conductive adhesive layer are welded by heating, thereby effectively fixing the actuating line, enabling efficient current conduction, and reducing product volume.

The foregoing are merely exemplary embodiments of the present disclosure and are not intended to limit the present disclosure. For those skilled in the art, various modifications and changes may be made to the present disclosure. Any modification, equivalent replacement, improvement, etc. made within the spirit and principles of the present disclosure shall be included in the protection scope of the present disclosure.

I/We claim:

1. An actuating assembly, comprising:
a circuit board, wherein the circuit board is provided with an integrated circuit component;
a fixing member arranged at an edge of the circuit board, wherein the fixing member comprises a first conductive layer, a conductive adhesive layer, and a cover plate, the first conductive layer, the conductive adhesive layer, and the cover plate are sequentially stacked, and the first conductive layer is electrically connected to the integrated circuit component and the conductive adhesive layer; and
an actuating line, wherein two ends of the actuating line extend into the conductive adhesive layer and are electrically connected to the conductive adhesive layer, and the actuating line and the circuit board form a closed ring structure.

2. The actuating assembly according to claim 1, wherein the fixing member is arranged on an end of the circuit board in a width direction of the circuit board,
the two ends of the actuating line respectively extend into the conductive adhesive layer via two ends of the conductive adhesive layer in a length direction of the conductive adhesive layer, and further extend to a middle part of the conductive adhesive layer, and
the first conductive layer covers a projection of the actuating line on the circuit board.

3. The actuating assembly according to claim 2, wherein the first conductive layer comprises two first conductive sheets, the two first conductive sheets are arranged on the circuit board and spaced apart from each other,
the conductive adhesive layer is arranged on the two first conductive sheets and fills in a gap between the two first conductive sheets,
the conductive adhesive layer is connected to the circuit board, and
two ends of the conductive adhesive layer extend beyond the two first conductive sheets and further extend to edges of the circuit board in a length direction of the circuit board respectively.

4. The actuating assembly according to claim 1, wherein the fixing member comprises two fixing members disposed at two ends of the circuit board in a length direction of the circuit board respectively,
the two ends of the actuating line extend into the conductive adhesive layer via two ends of the two fixing members, and the two ends of the two fixing members are located at a same side in a length direction of the two fixing members, and
the two first conductive layers of the two fixing members cover the projection of the actuating line on the circuit board.

5. The actuating assembly according to claim 2, wherein a part of the actuating line in the conductive adhesive layer is parallel to an edge of the conductive adhesive layer or has at least one curved segment.

6. The actuating assembly according to claim 1, wherein the first conductive layer comprises at least two first conductive components, and each conductive component is electrically connected to the conductive adhesive layer and the integrated circuit component.

7. The actuating assembly according to claim 6, further comprising a second conductive layer disposed between the conductive adhesive layer and the cover plate,
wherein the second conductive layer comprises at least two second conductive components electrically connected to the conductive adhesive layer, and positions of the at least two second conductive components are in one-to-one correspondence with positions of the at least two first conductive components.

8. The actuating assembly according to claim 6, further comprising a second conductive layer disposed between the conductive adhesive layer and the cover plate,
wherein the second conductive layer comprises one second conductive component electrically connected to the conductive adhesive layer, and a position of the one second conductive component is within the projection of the actuating line on the circuit board.

9. The actuating assembly according to claim 1, wherein the conductive adhesive layer is conductive in a direction perpendicular to a plane of the circuit board, and is insulating in a direction parallel to the plane of the circuit board.

10. The actuating assembly according to claim 9, wherein the conductive adhesive layer includes an insulating adhesive and conductive particles in the insulating adhesive.

11. The actuating assembly according to claim 1, wherein the two ends of the actuating line are respectively electrically connected to a positive electrode and a negative electrode through the conductive adhesive layer and the first conductive layer.

12. The actuating assembly according to claim 1, wherein when the circuit board supplies a current flowing on the actuating line, the actuating line generates Joule heat, a length of the actuating line changes.

13. An actuator, comprising:
an actuator body, wherein a top surface of the actuator body is provided with a first rotating shaft and a second rotating shaft;
a brake member disposed on the top surface of the actuator body and rotationally connected to the first rotating shaft, wherein the brake member is provided with a first rotating member;
a swing arm disposed on the top surface of the actuator body and rotationally connected to the second rotating shaft, wherein a second rotating member protrudes from the swing arm, and an end of the swing arm close to the brake member abuts against the brake member; and
a first driving member and a second driving member, wherein each of the first driving member and the second driving member comprises: a circuit board, a fixing member, and an actuating line,
wherein the circuit board is provided with an integrated circuit component, the fixing member is arranged at an edge of the circuit board and comprises a first conductive layer, a conductive adhesive layer, and a cover plate, the first conductive layer, the conductive adhesive layer, and the cover plate are sequentially stacked, the first conductive layer is electrically connected to the integrated circuit component and the conductive adhesive layer, two ends of the actuating line extend into the conductive adhesive layer and are electrically connected to the conductive adhesive layer, and the actuating line and the circuit board form a closed ring structure,
wherein the actuating line of the first driving member is a first actuating line, and the actuating line of the second driving member is a second actuating line, and
wherein the first driving member and the second driving member are both disposed on the top surface of the actuator body, the first actuating line of the first driving member is connected to the first rotating member, and the second actuating line of the second driving member is connected to the second rotating member.

14. The actuator according to claim 13, further comprising a mounting base, connected to the top surface of the actuator body, wherein the first driving member and the second driving member are respectively disposed on two sides of the mounting base, and an end of the actuator away from the mounting base extends to form a positioning part.

15. The actuator according to claim 14, further comprising a first elastic member and a fixing column, wherein the fixing column is mounted on the positioning part, and two ends of the first elastic member are respectively connected to the fixing column and an end of the swing arm away from the brake member.

16. The actuator according to claim 14, further comprising at least one steering block protruding from the mounting base, wherein the second actuating line is connected to the second rotating member after being steered by the at least one steering block.

17. The actuator according to claim 14, further comprising a second elastic member disposed between the brake member and the actuator body, wherein the second elastic member abuts against the brake member and the actuator body.

18. The actuator according to claim 14, wherein the mounting base is provided with an accommodating groove, and at least one of the first driving member or the second driving member is disposed in the accommodating groove.

19. The actuator according to claim 13, wherein at least one of the first driving member or the second driving member has a part embedded in the actuator body.

20. The actuator according to claim 13, wherein the conductive adhesive layer is conductive in a direction perpendicular to a plane of the circuit board, and is insulating in a direction parallel to the plane of the circuit board.
